(19) United States
(12) Patent Application Publication
(10) Pub. No.: US 2003/0173659 A1
(43) Pub. Date: Sep. 18, 2003

(54) Semiconductor package having oxidation-free copper wire

(75) Inventors: Sang-do Lee, Seoul (KR); Yong-suk Kwon, Bucheon-city (KR); Jong-jin Shin, Goyang-city (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: FAIRCHILD KOREA SEMICONDUCTOR LTD., Kyungki-do (KR)

(21) Appl. No.: 10/385,895

(22) Filed: Mar. 10, 2003

(30) Foreign Application Priority Data
Mar. 14, 2002 (KR) 2002-13816

(51) Int. Cl. H01L 23/48; H01L 23/52

(52) U.S. Cl. 257/690

(57) ABSTRACT

A semiconductor package having an oxidation free copper wire that connects a semiconductor chip and a pad is provided. The copper wire is coated with an oxidation free layer. The copper wire provides good electrical characteristics and reliability.

### BACKGROUND OF THE INVENTION

1. Field of the Invention

The present invention relates to a semiconductor package, and more particularly, to a semiconductor package having an oxidation free copper wire.

2. 2. Description of the Related Art

In general, a semiconductor package includes a semiconductor chip including a chip pad. The semiconductor chip is attached to a die pad of a lead frame, and an external terminal, i.e., an inner lead of the lead frame is electrically connected to the chip pad by a wire. As the wire, a gold (Au) wire is usually used. However, as widely known, a gold wire is expensive, and loses its reliability at high temperatures. Further, due to its softness, a gold wire easily deforms when subjected to external forces.

In accordance with recent tendencies requiring semiconductors of high speed, low power dissipation, and low costs, the use of a copper wire, having better electrical characteristics than a gold wire, in a semiconductor package is an active research area. A copper wire has lower electrical resistance than a gold wire, thereby improving for example, the operating speed of a semiconductor package. In addition, a copper wire is cheaper than a gold wire. Further, a gold wire has higher thermal conductivity than a gold wire, and thus more easily dissipates heat.

Even though a copper wire has various advantages as described above, it also has a problem in that its surface is easily oxidized when it is exposed to the outer environment, for example, during manufacturing in a wire bonding process. Accordingly, its reliability and electrical characteristics degrade. In other words, if the surface of the copper wire is oxidized, the resistance value of the wire increases, the electrical characteristics degrade, the junction intensity decreases, and thus the reliability of the wire generally degrades. If a ball at an end portion of a capillary is oxidized during a wire bonding process, it may partially block the end portion of the capillary from discharging, and thus a ball that is discharging from the capillary might not be formed into a circular shape. Even if ball forms a circular shape, its adhesiveness might decrease after the wire bonding process.

### BRIEF SUMMARY OF THE INVENTION

It is an object of the present invention to provide a semiconductor package that includes an oxidation free copper wire that does not lose reliability and electrical characteristics. An oxidation free layer prevents oxidation of the wire.

To achieve the object, there is provided a semiconductor package having a semiconductor chip pad and a terminal connected to the semiconductor chip pad with a coated wire, wherein the coated wire is copper wire coated with an oxidation free layer.

It is preferable that the oxidation free layer is made of a metallic material. The metallic material may be formed of one selected from palladium and platinum. It is preferable that the thickness of the oxidation free layer is from about 0.01 μm to about 0.5 μm. It is also preferable that the semiconductor package further comprises a semiconductor chip having the semiconductor chip pad; a lead frame pad to which the semiconductor chip is attached; and a molding material which fully surrounds the semiconductor chip, and a part of the lead frame pad terminal.

### BRIEF DESCRIPTION OF THE DRAWINGS

The above objects and advantages of the present invention will become more apparent by describing in detail preferred embodiments thereof with reference to the attached drawings in which:

FIG. 1 is a cross sectional view illustrating a semiconductor package having an oxidation free copper wire.

FIG. 2 is a perspective view illustrating a partially sectioned copper wire of the semiconductor package of FIG. 1.

FIGS. 3a and 3b are cross sectional views illustrating shapes in which a gold wire and a copper wire are bonded on a metallic electrode pad of the semiconductor chip, respectively.

FIG. 4 is a graph showing retracted thicknesses of an aluminum electrode pad according to changes of the temperature in the case of using a copper wire and a gold wire.

FIG. 5 is a graph for comparing resistance values according to thermal processing time in the case of using a copper wire and a gold wire.

FIG. 6 is a view showing a wire bonding process in manufacturing the semiconductor package of FIG. 1.

### DETAILED DESCRIPTION

The present invention now will be described more fully with reference to the accompanying drawings, in which preferred embodiments of the invention are shown. This invention may, however, be embodied in many different forms and should not be construed as being limited to the embodiments set forth herein.

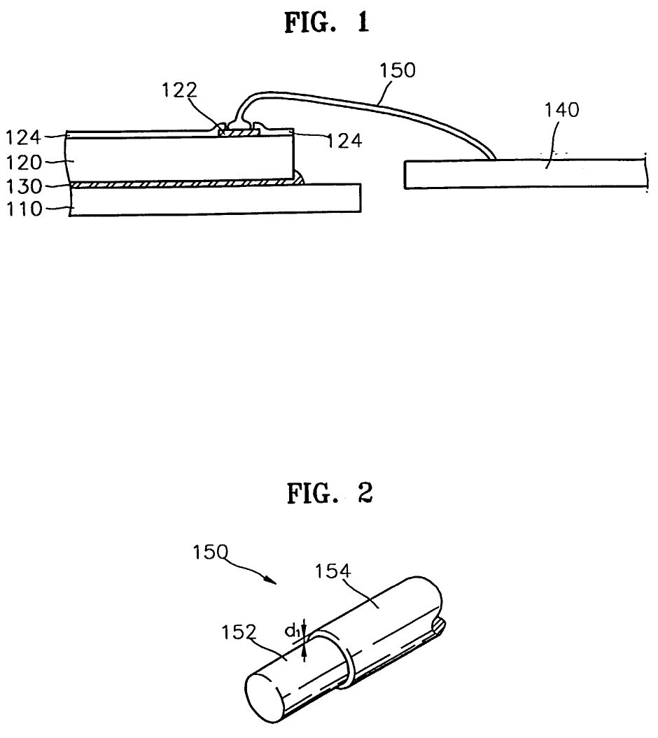

FIG. 1 is a cross sectional view showing a semiconductor package having an oxidation free copper wire, and FIG. 2 is a perspective view showing a partially sectioned copper wire of the semiconductor package of FIG. 1.

Referring to FIG. 1, a semiconductor chip 120 is adhered on top of a lead frame 110 by an adhering means, such as an epoxy resin 130. The semiconductor chip 120 may comprise any suitable electrical device including a horizontal or vertical power MOSFET (a vertical power MOSFET has a source region at one side of the semiconductor chip and a drain region at the other side of the semiconductor chip). On the front surface of the semiconductor chip 120 is formed an aluminum (Al) electrode pad 122. In the region that an aluminum (Al) electrode pad 122 is not provided, a protection layer 124 is formed on the front surface of the semiconductor chip 120. The aluminum electrode pad 122 and an inner lead 140 of the lead frame are electrically connected with an oxidation free coated copper (Cu) wire 150. The oxidation free coated copper (Cu) wire 150 can be formed using any suitable process. For example, an oxidation free layer may be coated on a copper wire using a sputtering process. Referring to FIG. 1, first and second ends of the coated wire 150 are respectively connected to the aluminum electrode pad 122 and the inner lead 140. Even though not shown in the figures, an upper portion of the lead frame pad 110, the semiconductor chip 120, the inner lead 140 of the lead frame and the oxidation free copper wire 150 are covered with an epoxy molding compound (EMC).

Referring to FIG. 2, the oxidation free, coated copper wire 150 has a structure including a copper wire 152 and an oxidation free layer 154 surrounding the circumference of the copper wire 152. The copper wire 152 may comprise pure copper, or substantially pure copper. Alternatively, a copper alloy wire that includes, for example, Cu with Ag mixed together could be used. The oxidation free layer 154 is made of a metallic material (e.g., noble metals), such as palladium or platinum. The thickness (d₁) of the oxidation free layer 154 can range from about 0.01 μm to about 0.5 μm. In the case of a gold wire, because the gold wire cannot preserve its shape due to its softness, it is difficult to use a gold wire with a diameter less than about 0.9 mm. In the case of a copper wire 152 inside of the coated copper wire (in which an oxidation free layer is present) 150, it is possible to use a copper wire 152 with a diameter between about 0.4 mm and about 0.9 mm. For instance, compared with the gold wire, the copper wire has a higher Young's modulus, which is a barometer indicating wire stiffness of whether wire shape is changed by external forces. Specifically, the copper wire has a Young's modulus of 8.8×10¹⁰N/m², while the gold wire has a Young's modulus of 13.6×10¹⁰N/m². In addition, the copper wire 152 costs just 40-50% of the gold wire, and even the coated copper wire (in which an oxidation free layer is present) 150, costs just 50-60% of the gold wire.

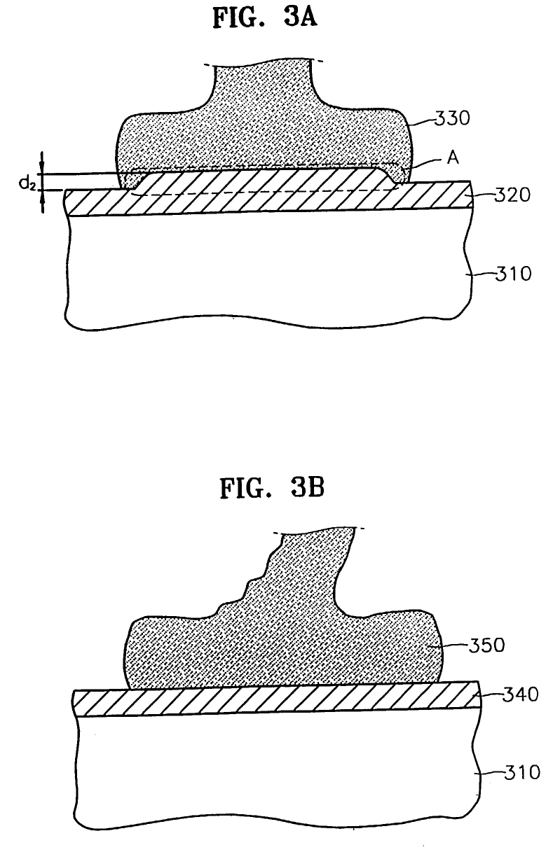

FIGS. 3a and 3b are cross sectional views showing shapes where a gold wire and a copper wire are bonded on a metallic electrode pad of a semiconductor chip.

Referring to FIG. 3a, if the gold wire 330 is bonded on top of the aluminum electrode pad 320 on the silicon semiconductor chip 310, an intermetallic growth between aluminum (Al) and gold (Au) occurs, thus aluminum of the aluminum electrode pad 320 grows inside the gold wire 330. Therefore, a portion (a portion indicated as “A” in FIG. 3a) of the aluminum electrode pad 320 is retracted inside the gold wire 330, and thus a contact area between the aluminum electrode pad 320 and the gold wire 330 is increased. If the contact area is increased, the contact resistance between the aluminum electrode pad 320 and the gold wire 330 is also increased. An electrical characteristic of the package is degraded.

The thickness (d₂) of a retraction of the aluminum electrode pad 320 increases as the temperature rises, and the rate of an increase of the retracted thickness increases rapidly over a certain temperature.

Referring to FIG. 3b, if the copper (Cu) wire 350 is bonded on top of the aluminum electrode pad 340 on the silicon semiconductor chip 310, an intermetallic growth between a copper (Cu) and aluminum (Al) occurs less than between gold (Au) and aluminum (Al). Thus an upper portion of the aluminum electrode pad 340 hardly grows inside the copper wire 350. Therefore, an abnormal increase in the contact area (as between the aluminum electrode pad 320 and the gold wire 330) is prevented.

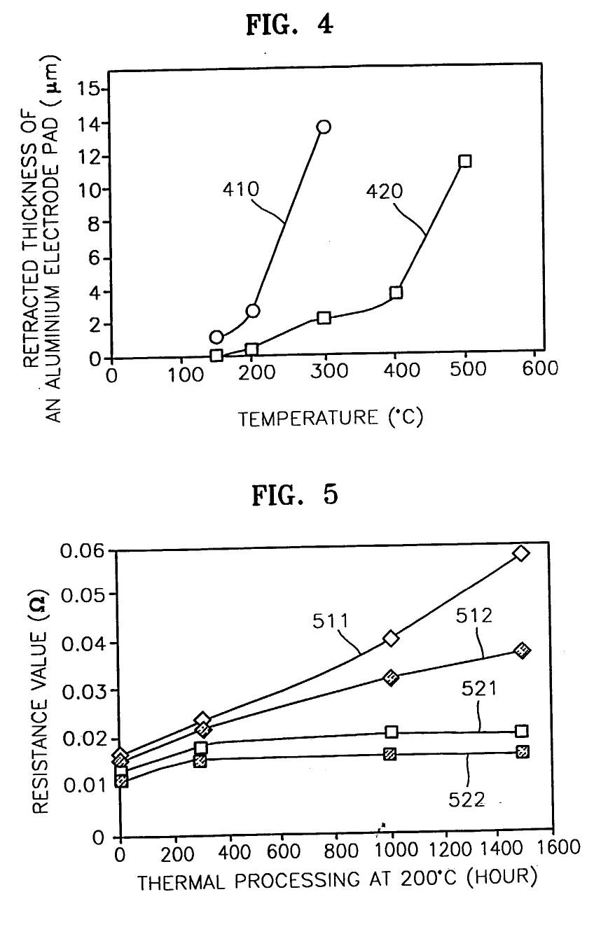

FIG. 4 is a graph showing retracted thicknesses of an aluminum electrode pad according to changes of the temperature in the case of using a copper wire and a gold wire.

Referring to FIG. 4, in the case of a wire bonding process using a gold wire (indicated as the reference numeral “410”), an aluminum electrode pad starts to retract towards the gold wire at about 150° C., and a thickness (d₂ in FIG. 3a) of retraction of the aluminum electrode pad 320 increases rapidly at temperatures over 200° C. Contrary to this, in the case of a wire bonding process using a copper wire (indicated as the reference numeral “420”), an aluminum electrode pad hardly retracts towards the copper wire at about 150° C., and a thickness of retraction of the aluminum electrode pad 320 increases rapidly at temperatures over 400° C.

FIG. 5 is a graph showing resistance values according to thermal processing time in the case of using a copper wire and a gold wire.

Referring to FIG. 5, in the case of performing a thermal process at about 200° C., after performing a wire bonding process on the aluminum electrode pad using a gold wire (indicated as the reference numeral “511”), a maximum resistance value is achieved; this means that the most active intermetallic growth occurs between gold and aluminum. In the case of performing a thermal process after performing a wire bonding process on the aluminum electrode pad containing copper and silicon, using a gold wire (indicated as the reference numeral “512”), the resistance is almost the same as the resistance in the case of performing a wire bonding process on the aluminum electrode pad using a gold wire, before a certain time, i.e., about 300 hours, but the resistance value is less than the resistance value in the case of performing a wire bonding process on the aluminum electrode pad using a gold wire.

In the case of performing a thermal process at 200° C., after performing a wire bonding process on the aluminum electrode pad using a copper wire (indicated as the reference numeral “521”), the resistance value continues to decrease during a certain period of time but hardly changes after the certain period of time. In the case of performing a thermal process after performing a wire bonding process on the aluminum electrode pad containing copper and silicon using a gold wire (indicated as the reference numeral “522”), a minimum resistance value is achieved.

Generally, the phenomenon that a resistance value is lower in the case of using a copper wire than the case of using a gold wire is based on two factors. First, intermetallic growths occur less in the case of using the copper wire (between copper and aluminum, or copper and aluminum containing copper and silicon) than in the case of using the gold wire. Second, while a non-resistance of the copper is measured at 1.67 μΩcm at a temperature of 20° C., a non-resistance of the gold is measured at 2.4 μΩcm at a temperature of 20° C.

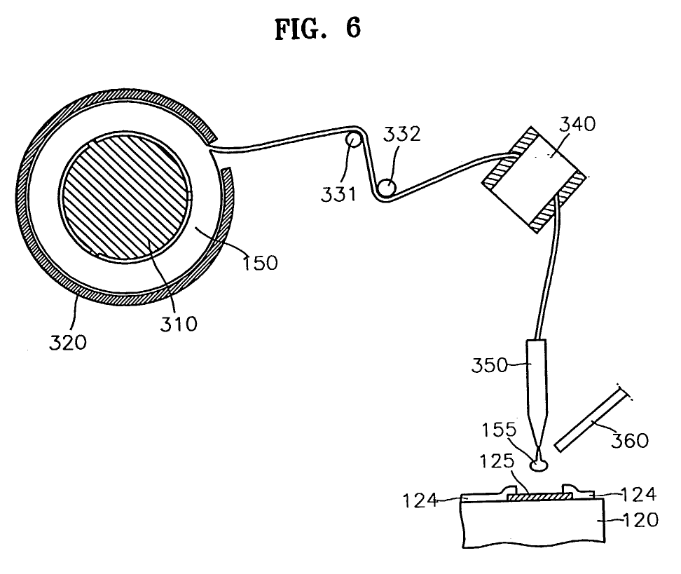

FIG. 6 is a view showing a wire bonding process in manufacturing the semiconductor package of FIG. 1.

Referring to FIG. 6, the coated copper wire 150 which includes the oxidation free layer (154 in FIG. 2) covers a wire spool 310 in the inner space defined by the cover 320 inside a wire storage vessel. The wire spool 310 is rotatable. The conventional wire storage vessel includes the cover 320 and a nitrogen gas implanter which passes through the cover and supplies nitrogen gas (N₂) in the space where a copper wire exits to prevent oxidation. However, the present invention does not require this kind of nitrogen gas implanter, since an oxidation free layer is already surrounding the circumference of the copper wire. In addition, the cover has an open portion, so that the coated copper wire 150 which includes the oxidation free layer, can be provided outwardly. The coated copper wire 150, on which an oxidation free layer is coated, is provided into a capillary 350 through the first roller 331, the second roller 332, and the supporter 340. The coated copper wire 150 forms a ball 155 outside of the capillary 350 by a strong discharge. The ball 155 is bonded on top of the surface of the aluminum electrode pad 125 on top of the semiconductor chip 120. A protection layer 124 is also shown. On the other hand, according to an embodiment of the present invention, as the discharge is occurring at one end portion of the capillary 350, it causes the copper and the oxidation free layer to melt and oxidize. An additional gas nozzle 360 (e.g., that dispenses an inert gas) can be used to prevent the oxidation process.

It is noted that the present invention is not limited to the preferred embodiments described above, and it is apparent that variations and modifications by those skilled in the art can be performed within the spirit and scope of the present invention.

As described above, the semiconductor package according to the present invention provides advantages as follows. First, the copper wire provides effects such as low electrical resistance, high stiffness, low costs, increased life expectancy at a high temperature, high heat conductivity and low heat generation, etc. Second, the copper wire provides effects such as increased electrical characteristics and reliability of the semiconductor package by preventing oxidation and increasing adhesion intensity as compared with the case of using only a gold wire.

What is claimed is:

1. A semiconductor package comprising:
a semiconductor chip pad;
a terminal; and
a coated wire, the coated wire comprises a copper wire coated with an oxidation free layer, wherein the coated wire connects the terminal and the semiconductor chip pad.

2. The semiconductor package of claim 1, wherein the oxidation free layer comprises a metallic material.

3. The semiconductor package of claim 2, wherein the metallic material is selected from the group consisting of palladium and platinum.

4. The semiconductor package of claim 1, wherein a thickness of the oxidation free layer is from about 0.01 μm to about 0.5 μm.

5. The semiconductor package of claim 1, further comprising:
a semiconductor chip having the semiconductor chip pad;
a lead frame that includes the terminal; and
a molding material which fully surrounds the semiconductor chip, and a part of the lead frame.

6. The semiconductor package of claim 1 wherein the semiconductor chip pad comprises aluminum.

7. A method for making a semiconductor die package, the method comprising:
providing a semiconductor chip pad and a terminal; and
bonding a first end of a coated wire to the semiconductor chip pad and a second end of the coated wire to the terminal, wherein the coated wire comprises a copper wire coated with oxidation free layer, and wherein the coated wire connects the terminal and the semiconductor chip pad.

8. The method of claim 7 wherein the oxidation free layer comprises a metallic material selected from the group consisting of palladium and platinum, and wherein a thickness of the oxidation free layer is from about 0.01 μm to about 0.5 μm.

9. A semiconductor package comprising:
a semiconductor chip pad;
a terminal; and
a coated wire, the coated wire being comprised of a copper alloy wire coated with an oxidation free layer, wherein the coated wire connects the terminal and the semiconductor chip pad.

10. The semiconductor package of claim 9, wherein the oxidation free layer is comprised of a metallic material.

11. The semiconductor package of claim 10, wherein the metallic material is selected from the group consisting of palladium and platinum.

12. The semiconductor package of claim 9, wherein a thickness of the oxidation free layer is from about 0.01 μm to about 0.5 μm.

13. The semiconductor package of claim 9, further comprising:
a semiconductor chip having the semiconductor chip pad;
a lead frame that includes the terminal; and
a molding material which fully surrounds the semiconductor chip and a part of the lead frame.

14. The semiconductor package of claim 9, wherein the copper alloy wire is comprised of a copper alloy mixed with a material selected from the group consisting of Ag and Au.

15. The semiconductor package of claim 9, wherein the semiconductor chip pad is comprised of aluminum.

16. A method for making a semiconductor die package, the method comprising:
providing a semiconductor chip pad and a terminal; and
bonding a first end of a coated wire to the semiconductor chip pad and a second end of the coated wire to the terminal, wherein the coated wire comprises a copper alloy wire coated with oxidation free layer, and wherein the coated wire connects the terminal and the semiconductor chip pad.

17. The method of claim 16, wherein the oxidation free layer comprises a metallic material selected from the group consisting of palladium and platinum, and wherein a thickness of the oxidation free layer is from about 0.01 μm to about 0.5 μm.

18. The method of claim 16, wherein the copper alloy wire is comprised of a copper alloy mixed with a material selected from the group consisting of Ag and Au.
